(19) United States
(12) Patent Application Publication
(10) Pub. No.: US 2025/0252992 A1
(43) Pub. Date: Aug. 7, 2025

(54) RECEIVING CIRCUIT

(71) Applicant: SAMSUNG ELECTRONICS CO., LTD., Suwon-si (KR)

(72) Inventors: Younggil Go, Suwon-si (KR); Donghyeok Jeong, Suwon-si (KR); Kihan Kim, Suwon-si (KR); Yoo-Chang Sung, Suwon-si (KR); Yunsoo Lee, Suwon-si (KR); Kiho Kim, Suwon-si (KR); Jang Hoo Kim, Suwon-si (KR); Jinhyeok Baek, Suwon-si (KR); ChangSik Yoo, Suwon-si (KR); Hojun Chang, Suwon-si (KR); Youngsin Jo, Suwon-si (KR)

(21) Appl. No.: 18/975,461

(22) Filed: Dec. 10, 2024

(30) Foreign Application Priority Data
Feb. 1, 2024 (KR) 10-2024-0016059
Mar. 26, 2024 (KR) 10-2024-0041372

(51) Int. Cl. G11C 11/409; H03H 11/04

(52) U.S. Cl. CPC G11C 11/409; H03H 11/04

(57) ABSTRACT

Disclosed is a receiving circuit, which includes a first input transistor, a second input transistor, a first equalization transistor, a second equalization transistor, a filter circuit, and an input capacitance adjustment circuit. The first input transistor receives a first input signal through a first input node. The second input transistor receives a second input signal through a second input node. The first equalization transistor is connected in parallel with the first input transistor. The second equalization transistor is connected in parallel with the second input transistor. The filter circuit filters the first input signal and includes one or more internal nodes. The input capacitance adjustment circuit adjusts voltage levels of the one or more internal nodes based on an operating mode of a semiconductor memory device.

### CROSS-REFERENCE TO RELATED APPLICATIONS

This application claims priority under 35 U.S.C. § 119 to Korean Patent Application Nos. 10-2024-0016059, filed on Feb. 1, 2024, and 10-2024-0041372, filed on Mar. 26, 2024, in the Korean Intellectual Property Office, the disclosures of which are incorporated by reference herein in their entireties.

### BACKGROUND

Recently, as the integration degree of semiconductor memory devices increases and the data rate increases, the performance of receiving circuits is becoming important to compensate for losses that may occur in the process of receiving data signals at high speed through interface channels. For example, the receiving circuit may include an equalization circuit, and the equalization circuit may be used to improve the integrity of received data signals. For example, the receiving circuit may employ various types of equalization circuits, and in particular, an ACCE (AC coupled equalizer) circuit, which uses an AC (alternating current) coupling capacitor and a shunt resistor, improves operating characteristics in a write mode of a semiconductor memory device.

### SUMMARY

Implementations of the present disclosure provide a receiving circuit that improves the integrity of data signals.

According to some implementations of the present disclosure, a receiving circuit includes a first input transistor, a second input transistor, a first equalization transistor, a second equalization transistor, a filter circuit, and an input capacitance adjustment circuit. The first input transistor is connected between a first common node and a first output node and receives a first input signal through a first input node. The second input transistor is connected between the first common node and a second output node and receives a second input signal through a second input node. The first equalization transistor is connected in parallel with the first input transistor. The second equalization transistor is connected in parallel with the second input transistor. The filter circuit filters the first input signal and includes one or more internal nodes. The input capacitance adjustment circuit adjusts voltage levels of the one or more internal nodes based on an operating mode of a semiconductor memory device. The operating mode of the semiconductor memory device includes a write mode and a read mode.

According to some implementations of the present disclosure, a receiving circuit includes a first input transistor, a second input transistor, an equalization circuit, and an input capacitance adjustment circuit. The first input transistor is connected between a first common node and a first output node and receives a first input signal through a first input node. The second input transistor is connected between the first common node and a second output node and receives a second input signal through a second input node. The equalization circuit includes one or more internal nodes and equalizes the first input signal. The input capacitance adjustment circuit adjusts voltage levels of the one or more internal nodes based on an operating mode of a semiconductor memory device. The operating mode of the semiconductor memory device includes a write mode and a read mode.

According to some implementations of the present disclosure, a receiving circuit includes a first input transistor, a second input transistor, a first equalization transistor, a second equalization transistor, a filter circuit, and an input capacitance adjustment circuit. The first input transistor is connected between a first common node and a first output node and receives a first input signal through a first input node. The second input transistor is connected between the first common node and a second output node and receives a second input signal through a second input node. The first equalization transistor is connected in parallel with the first input transistor. The second equalization transistor is connected in parallel with the second input transistor. The filter circuit filters the first input signal, and includes a first filter node, a second filter node, and a third filter node. The input capacitance adjustment circuit adjusts voltage levels of the first filter node and the second filter node based on an operating mode of a semiconductor memory device. The operating mode of the semiconductor memory device includes a write mode and a read mode. The filter circuit includes a first sub-filter circuit and a second sub-filter circuit. The first sub-filter circuit is connected between the first input node and the first filter node. The second sub-filter circuit connected between the second filter node and the first filter node. The first sub-filter circuit includes a first MOS capacitor and a first resistance network. The first MOS capacitor connected between the first input node and a third filter node. The first resistance network is connected between the third filter node and the first filter node and has a variable first composite resistance value.

### BRIEF DESCRIPTION OF THE FIGURES

The above and other features of the present disclosure will become apparent by describing in detail implementations thereof with reference to the accompanying drawings.

FIG. 1 is a block diagram illustrating a receiving circuit, according to some implementations of the present disclosure.

FIG. 2 is a circuit diagram illustrating a receiving circuit, according to some implementations of the present disclosure.

FIG. 3 is a diagram for describing an operation of a receiving circuit of FIG. 2.

FIG. 4 is a graph for describing a state of a first MOS capacitor included in a first sub-filter circuit of FIG. 2 in response to an operating mode of a semiconductor memory device and enabling/disabling of an equalization circuit.

FIGS. 5 and 6 are flowcharts illustrating some implementations of an operation of a receiving circuit of FIG. 2.

FIG. 7 is a circuit diagram illustrating a receiving circuit, according to some implementations of the present disclosure.

FIG. 8 is a diagram for describing an operation of a receiving circuit of FIG. 7.

FIGS. 9A and 9B are eye diagrams for describing improvement in performance of receiving circuits of FIG. 2 or FIG. 7.

FIG. 10 is a flowchart illustrating some implementations of an operation of a receiving circuit of FIG. 7.

FIG. 11 is a circuit diagram illustrating a receiving circuit, according to some implementations of the present disclosure.

FIG. 12 is a diagram for describing an operation of a receiving circuit of FIG. 11.

FIG. 13 is a graph for describing a change in an input signal according to a change in a composite resistance value of a resistance network of FIG. 11.

FIG. 14 is a flowchart illustrating some implementations of an operation of a receiving circuit of FIG. 11.

FIG. 15 is a graph for describing improvement in performance of a receiving circuit, according to some implementations of the present disclosure.

FIG. 16 is a block diagram illustrating a semiconductor memory device including a receiving circuit, according to some implementations of the present disclosure.

### DETAILED DESCRIPTION

Hereinafter, implementations of the present disclosure will be described in detail and clearly to such an extent that one ordinarily skilled in the art can implement the present disclosure.

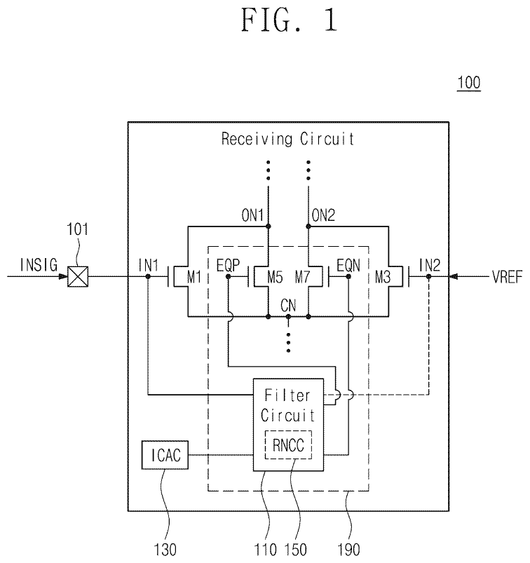

FIG. 1 is a block diagram illustrating a receiving circuit, according to some implementations of the present disclosure.

Referring to FIG. 1, a receiving circuit 100 includes a first input transistor M1, a second input transistor M3, a first equalization transistor M5, a second equalization transistor M7, a filter circuit 110, and an input capacitance adjustment circuit (ICAC) 130. For example, the receiving circuit 100 may be included in an input/output circuit in a semiconductor memory device and may be implemented one by one for each input/output pad 101, but the scope of the present disclosure is not limited thereto. For example, the receiving circuit 100 receives signals from an external host device through the input/output pad 101, and may compensate for the frequency responses of the received signals to compensate for attenuated signal components during transmission of signals through an interface channel, etc.

The first input transistor M1 may be connected between a first common node CN and a first output node ON1, and may receive a first input signal INSIG through a first input node IN1. The second input transistor M3 may be connected between the first common node CN and a second output node ON2, and may receive a second input signal VREF through a second input node IN2. For example, the first input signal INSIG may be a single ended signal including information such as a command, an address, or data, and the second input signal VREF may be a reference signal for determining whether a logic level of the first input signal INSIG is logic high or logic low.

The first equalization transistor M5 may be connected in parallel with the first input transistor M1, and the second equalization transistor M7 may be connected in parallel with the second input transistor M3. For example, the first equalization transistor M5 may be connected between the first common node CN and the first output node ON1, and the second equalization transistor M7 may be connected between the first common node CN and the second output node ON2.

The filter circuit 110 filters the first input signal INSIG and may include one or more internal nodes. For example, an internal node included in the filter circuit 110 may be referred to as a ‘filter node.’

In some implementations, the first equalization transistor M5, the second equalization transistor M7, and the filter circuit 110 may form an equalization circuit 190, and the equalization circuit 190 may equalize the first input signal INSIG and may perform an equalization operation to compensate for attenuated signal components of the first input signal INSIG. For example, the equalization circuit 190 may be some components of the receiving circuit 100 that perform the equalization operation in the receiving circuit 100.

The input capacitance adjustment circuit 130 may adjust voltage levels of one or more internal nodes included in the filter circuit 110 based on the operating mode of a semiconductor memory device. For example, the input capacitance adjustment circuit 130 may adjust a voltage level of the filter node. For example, the operating mode of the semiconductor memory device may include a write mode and a read mode, and the input capacitance adjustment circuit 130 may adjust an input capacitance of the receiving circuit 100 in each of the write mode and the read mode by adjusting the voltage level of the filter node. The write mode may be an operating mode that receives a signal from an external host device through the input/output pad 101, and the read mode may be an operating mode that transmits a signal to an external host device through the input/output pad 101. Although not illustrated in FIG. 1, the semiconductor memory device may include a transmission driver connected to the input/output pad 101 and distinct from the receiving circuit 100, and in the read mode, a signal may be transmitted to an external host device through the transmission driver and the input/output pad 101. For example, the input capacitance adjustment circuit 130 may reduce the input capacitance of the receiving circuit 100 in each of the write mode and the read mode, and the reduction of the input capacitance may cause the signal integrity of the first input signal INSIG to be improved.

For example, the one or more internal nodes included in the filter circuit 110 may include a first node and a second node. The input capacitance adjustment circuit 130 may be directly connected to the first node and, based on the operating mode of the semiconductor memory device, may pull up, pull down, or float a voltage level of the first node to adjust the voltage levels of the one or more internal nodes. An input capacitance adjustment circuit 130 may be coupled directly to the second node and may adjust the voltage levels of the one or more internal nodes by pulling down or floating a voltage level of the second node in response to that the semiconductor memory device operates in a specific operating mode and the receiving circuit 100 enables/disables the equalization circuit.

In some implementations, the receiving circuit 100 may further include a reflection noise compensation circuit (RNCC) 150 included in the filter circuit 110. The reflection noise compensation circuit 150 may include one or more resistance networks, may adjust composite resistance values of the resistance networks in response to that the semiconductor memory device operates in a specific operating mode, the receiving circuit 100 enables/disables the equalization circuit, and a value of the reflection noise caused by an interface channel is above a specific level, and may improve the signal integrity of the first input signal INSIG by reducing the noise components of the first input signal INSIG by adjusting the composite resistance values.

With the above configuration, the receiving circuit according to some implementations of the present disclosure may adjust the voltage levels of one or more internal nodes included in the filter circuit based on the operating mode of the semiconductor memory device including the write mode and the read mode. The receiving circuit may adjust the voltage levels of the one or more internal nodes in response to that the semiconductor memory device operates in a specific operating mode and the receiving circuit enables/disables the equalization circuit. The receiving circuit adjusts composite resistance values of the resistance networks in response to that the semiconductor memory device operates in a specific operating mode, the receiving circuit enables/disables the equalization circuit, and the magnitude of the reflection noise is above a specific level. The input capacitance of the receiving circuit may be reduced by adjusting the voltage levels of the one or more internal nodes, and the noise component of the input signal may be reduced by adjusting the composite resistance values of the resistance networks. The receiving circuit may improve signal integrity of the input signal by reducing the input capacitance or reducing the noise component.

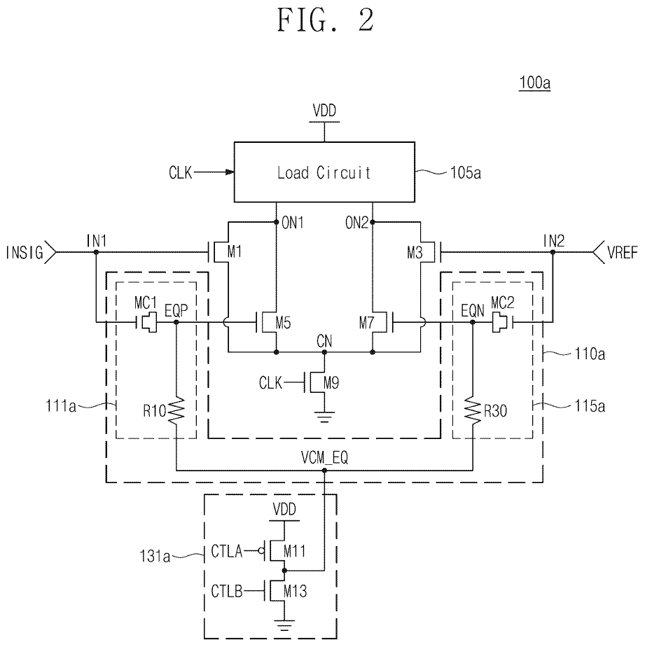

FIG. 2 is a circuit diagram illustrating a receiving circuit, according to some implementations of the present disclosure.

Referring to FIGS. 1 and 2, a receiving circuit 100a may correspond to the receiving circuit 100. The receiving circuit 100a includes a load circuit 105a, the first input transistor M1, the second input transistor M3, the first equalization transistor M5, the second equalization transistor M7, a bias transistor M9, a filter circuit 110a, and a first adjustment circuit 131a. In FIGS. 1 and 2, components having the same reference numerals perform the same or similar functions, the filter circuit 110a may correspond to the filter circuit 110, and the first adjustment circuit 131a may correspond to the input capacitance adjustment circuit 130.

The filter circuit 110a includes a first sub-filter circuit 111a and a second sub-filter circuit 115a. The first sub-filter circuit 111a may be connected between the first input node IN1 and a first filter node VCM_EQ and may filter the first input signal INSIG. The second sub-filter circuit 115a may be connected between the second input node IN2 and the first filter node VCM_EQ and may filter the second input signal VREF. The first sub-filter circuit 111a includes a first MOS capacitor MC1 and a first resistor R10. The second sub-filter circuit 115a includes a second MOS capacitor MC2 and a second resistor R30. The first MOS capacitor MC1 may be connected between the first input node IN1 and a second filter node EQP, and the first resistor R10 may be connected between the second filter node EQP and the first filter node VCM_EQ. The second MOS capacitor MC2 may be connected between the second input node IN2 and a third filter node EQN, and the second resistor R30 may be connected between the third filter node EQN and the first filter node VCM_EQ. For example, the first sub-filter circuit 111a and the second sub-filter circuit 115a may be high-pass filters that pass only high-frequency components of the first input signal INSIG and the second input signal VREF. In response to the equalization circuit of the receiving circuit 100a being enabled (or when the receiving circuit 100a enables the equalization operation) as described above with reference to FIG. 1, high-frequency components that passed through the first sub-filter circuit 111a and the second sub-filter circuit 115a may be amplified by the first equalization transistor M5 and the second equalization transistor M7, and may be output to the first output node ON1 and the second output node ON2 as equalized signals by adding output signals of the first input transistor M1 and the second input transistor M3.

The first adjustment circuit 131a includes a first adjustment transistor M11 and a second adjustment transistor M13. The first adjustment transistor M11 may be connected between a first power supply voltage VDD and the first filter node VCM_EQ, and the second adjustment transistor M13 may be connected between a second power supply voltage GND and the first filter node VCM_EQ. The first adjustment transistor M11 may operate based on a first control signal CTLA, and the second adjustment transistor M13 may operate based on the second control signal CTLB. For example, the first adjustment transistor M11 may have a gate terminal for receiving the first control signal CTLA, and the second adjustment transistor M13 may have a gate terminal for receiving the second control signal CTLB.

In some implementations, the first adjustment circuit 131a may adjust a voltage level of the first filter node VCM_EQ based on the operating mode of the semiconductor memory device. The input capacitance of the receiving circuit 100a may be adjusted by adjusting the voltage level of the first filter node VCM_EQ.

The load circuit 105a may be connected between the first power supply voltage VDD, and the first output node ON1 and the second output node ON2, and operates as a load of all of the first input transistor M1, the second input transistor M3, the first equalization transistor M5, and the second equalization transistor M7, based on a clock signal CLK, and the bias transistor M9 may apply a bias current to each of the first input transistor M1, the second input transistor M3, the first equalization transistor M5, and the second equalization transistor M7.

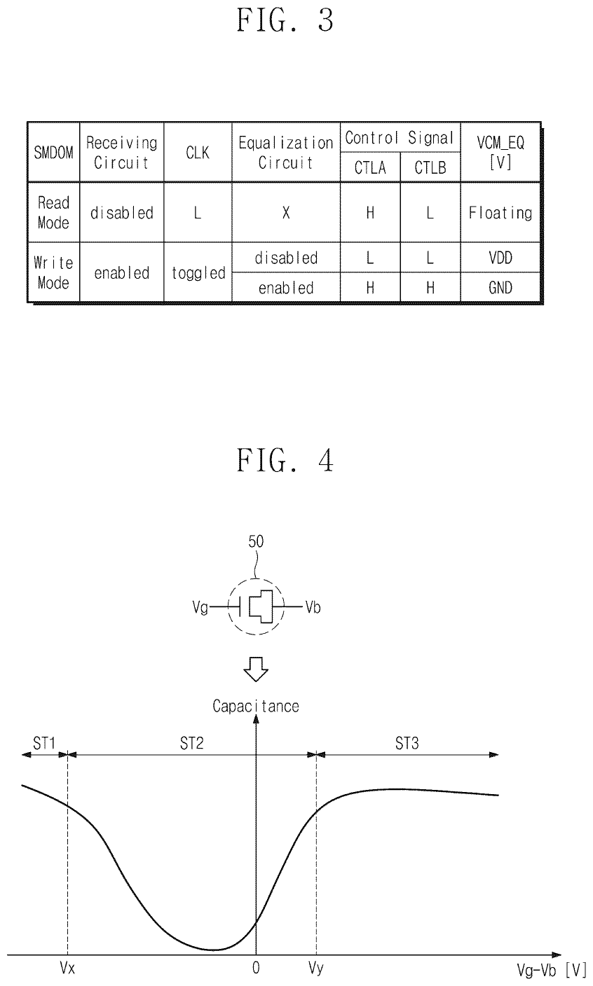

FIG. 3 is a diagram for describing an operation of a receiving circuit of FIG. 2.

Referring to FIGS. 2 and 3, the receiving circuit 100a may operate based on an operating mode SMDOM of the semiconductor memory device.

The receiving circuit 100a may be disabled when the operating mode SMDOM of the semiconductor memory device is the ‘read mode’ (e.g., when the semiconductor memory device operates in the read mode). The receiving circuit 100a may be enabled when the operating mode SMDOM of the semiconductor memory device is the ‘write mode’ (e.g., when the semiconductor memory device operates in the write mode).

For example, in the read mode, the clock signal CLK corresponding to logic low is applied to a gate terminal of the bias transistor M9 to float the first common node CN, and the voltage levels of the first output node ON1 and the second output node ON2 connected to the load circuit 105a may be charged with the first power supply voltage VDD, thereby disabling the receiving circuit 100a. For example, in the write mode, the toggling clock signal CLK is applied to the gate terminal of the bias transistor M9 so that the first common node CN is periodically charged with the second power supply voltage GND and the receiving circuit 100a may be enabled (e.g., the receiving circuit 100a may operate normally).

In some implementations, in the read mode, the receiving circuit 100a may disable or enable the equalization circuit (e.g., don't care (X)), and the receiving circuit 100a may reduce the input capacitance of the receiving circuit 100a by floating the first filter node VCM_EQ. For example, in response to that the semiconductor memory device operates in the read mode, the first control signal CTLA may correspond to logic high, the second control signal CTLB may correspond to logic low, and the first adjustment circuit 131a may float the first filter node VCM_EQ by turning off both the first adjustment transistor M11 and the second adjustment transistor M13 regardless of whether the equalization operation is enabled. The input capacitance of the receiving circuit 100a may be measured at the first input node IN1, and the main factors contributing to determining the value of the input capacitance may be parasitic capacitances of the first input transistor M1 and a capacitance of the first MOS capacitor MC1. For example, in response to that the semiconductor memory device operates in the read mode, when the receiving circuit 100a is disabled and the first filter node VCM_EQ is floating, one end of the first MOS capacitor MC1 (e.g., the filter node EQP) may be floating, so the capacitance of the first MOS capacitor MC1 may be relatively reduced (e.g., the first MOS capacitor MC1 may be in a depletion state). As the capacitance of the first MOS capacitor MC1, which is a factor contributing to determining the value of the input capacitance of the receiving circuit 100a, decreases, the input capacitance of the receiving circuit 100a may also decrease.

In some implementations, in the write mode, the receiving circuit 100a may disable or enable the equalization circuit depending on the communication environment of an interface channel.

For example, when the equalization circuit is disabled, the receiving circuit 100a may reduce the input capacitance of the receiving circuit 100a by adjusting the voltage level of the first filter node VCM_EQ to the first power supply voltage VDD. For example, in response to that the semiconductor memory device operates in the write mode and the receiving circuit 100a disables the equalization circuit, both the first control signal CTLA and the second control signal CTLB may correspond to logic low, and the first adjustment circuit 131a turns on the first adjustment transistor M11 and turns off the second adjustment transistor M13 to adjust the voltage level of the first filter node VCM_EQ to the first power supply voltage VDD (i.e., a pull-up operation is performed.). For example, in response to that the semiconductor memory device operates in the write mode and the receiving circuit 100a disables the equalization circuit, when the receiving circuit 100a is enabled and the voltage level of the first filter node VCM_EQ is adjusted to the first power supply voltage VDD, a normal input signal is applied to one end (e.g., the input node IN1) of the first MOS capacitor MC1 and the first power supply voltage VDD is applied to the other end (e.g., the filter node EQP) of the first MOS capacitor MC1, so that the capacitance of the first MOS capacitor MC1 may be relatively reduced (e.g., the first MOS capacitor MC1 is in a depletion state), and the input capacitance of the receiving circuit 100a may also be reduced.

For example, when the equalization circuit is enabled, the receiving circuit 100a may operate normally by adjusting (pulling down) the first filter node VCM_EQ to the second power supply voltage GND (e.g., the first MOS capacitor MC1 may have an inversion state.).

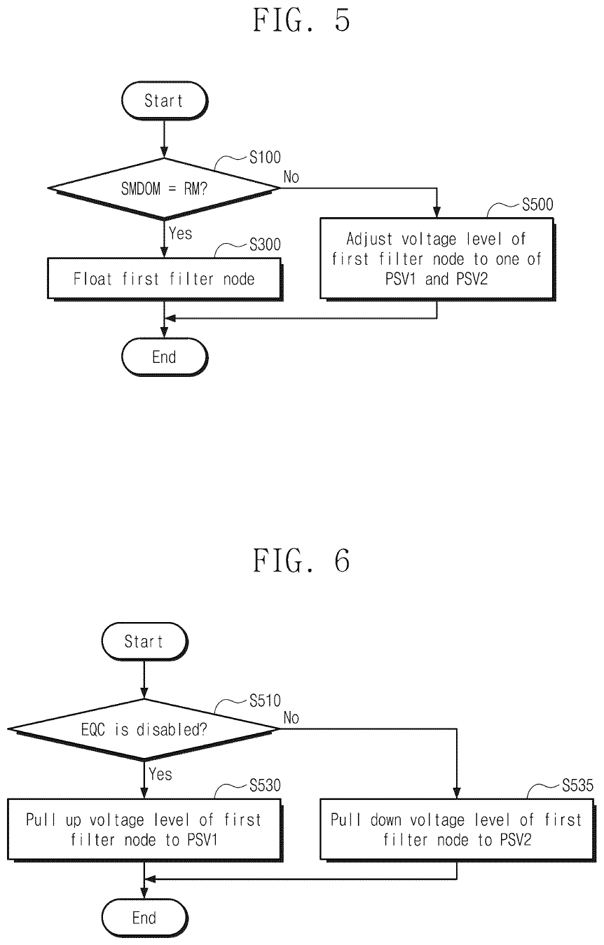

FIG. 4 is a graph for describing a state of a first MOS capacitor included in a first sub-filter circuit of FIG. 2 in response to an operating mode of a semiconductor memory device and enabling/disabling of an equalization circuit.

In FIG. 4, a capacitance-voltage (C-V) characteristic curve of a MOS capacitor 50 is illustrated.

Referring to FIG. 4, when a gate voltage Vg and a body voltage Vb are applied to both ends of the MOS capacitor 50, as a voltage difference Vg-Vb between both ends of the MOS capacitor 50 changes, the state of the MOS capacitor 50 and the capacitance of the MOS capacitor 50 may change.

For example, when the voltage difference Vg-Vb is lower than or equal to Vx, the MOS capacitor 50 may have a first state ST1, when the voltage difference Vg-Vb is higher than Vx and lower than or equal to Vy, the MOS capacitor 50 may have a second state ST2, and when the voltage difference Vg-Vb is higher than Vy, the MOS capacitor 50 may have a third state ST3. The first state ST1 may be an accumulation state, the second state ST2 may be a depletion state, and the third state ST3 may be an inversion state.

FIGS. 2 to 4, in response to that the semiconductor memory device operates in the read mode, the voltage difference across the first MOS capacitor MC1 of FIG. 2 becomes higher than Vx and lower than or equal to Vy, so the first MOS capacitor MC1 may be in the depletion state. In response to that the semiconductor memory device operates in the write mode and the receiving circuit 100a disables the equalization circuit, the voltage difference across the first MOS capacitor MC1 becomes higher than Vx and lower than or equal to Vy, so the first MOS capacitor MC1 may be in the depletion state. In response to that the semiconductor memory device operates in the write mode and the receiving circuit 100a enables the equalization circuit, the voltage difference across the first MOS capacitor MC1 becomes higher than Vy, so the first MOS capacitor MC1 may be the inversion state.

FIGS. 5 and 6 are flowcharts illustrating some implementations of an operation of a receiving circuit of FIG. 2.

Referring to FIGS. 2 and 5, it may be determined whether the operating mode SMDOM of the semiconductor memory device including the receiving circuit 100a is a read mode RM (S100).

When the operating mode SMDOM of the semiconductor memory device is the read mode RM (YES in S100), the first filter node VCM_EQ may be floated (S300).

When the operating mode SMDOM of the semiconductor memory device is not the read mode RM (e.g., the write mode) (NO in S100), the voltage level of the first filter node VCM_EQ may be adjusted to one of a first power supply voltage PSV1 and a second power supply voltage PSV2 (S500).

In some implementations, the first power voltage PSV1 may be VDD and the second power voltage PSV2 may be GND.

In some implementations, operation S100 may be performed by a control logic circuit of the semiconductor memory device, operations S300 and S500 may be performed by the receiving circuit 100a, the input capacitance adjustment circuit, or the first adjustment circuit 131a, and the control logic circuit may provide control signals (e.g., CTLA and CTLB) for operations S300 and S500 to the receiving circuit 100a.

Referring to FIGS. 2, 5, and 6, in operation S500, it may be determined whether an equalization circuit EQC is disabled (S510).

When the equalization circuit EQC is disabled (YES in S510), the voltage level of the first filter node VCM_EQ may be pulled up to the first power supply voltage PSV1 (S530).

When the equalization circuit EQC is enabled (NO in S510), the voltage level of the first filter node VCM_EQ may be pulled down to the second power supply voltage PSV2 (S535).

In some implementations, operations S530 and S535 may be performed by the receiving circuit 100a, the input capacitance adjustment circuit, or the first adjustment circuit 131a, and the control logic circuit may provide the control signals for operations S530 and S535 to the receiving circuit 100a.

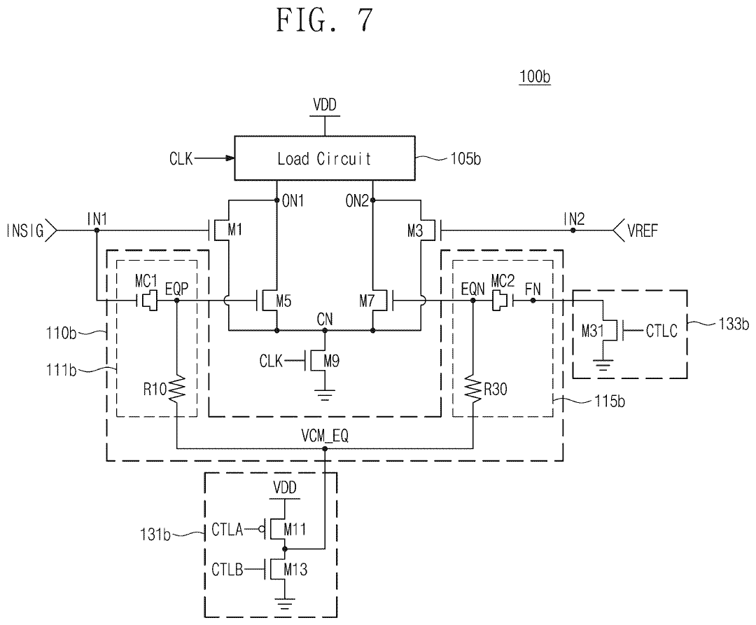

FIG. 7 is a circuit diagram illustrating a receiving circuit, according to some implementations of the present disclosure.

Referring to FIGS. 1, 2, and 7, a receiving circuit 100b may correspond to the receiving circuit 100 and the receiving circuit 100a. The receiving circuit 100b includes a load circuit 105b, the first input transistor M1, the second input transistor M3, the first equalization transistor M5, the second equalization transistor M7, the bias transistor M9, a filter circuit 110b, a first adjustment circuit 131b, and a second adjustment circuit 133b. In FIGS. 2 and 7, components having the same reference numerals may perform the same or similar functions, the load circuit 105b may correspond to the load circuit 105a, the filter circuit 110b may correspond to the filter circuit 110a, and the first adjustment circuit 131b may correspond to the first adjustment circuit 131a. For example, the receiving circuit 100b may include the same or similar configuration as the receiving circuit 100a except that it further includes the second adjustment circuit 133b. Thus, additional descriptions of components that are the same as those of FIG. 2 will be omitted to avoid redundancy.

The filter circuit 110b includes a first sub-filter circuit 111b and a second sub-filter circuit 115b. The first sub-filter circuit 111b may be connected between the first input node IN1 and the first filter node VCM_EQ and may filter the first input signal INSIG. The second sub-filter circuit 115b may be connected between the second input node IN2 and the first filter node VCM_EQ and may filter the second input signal VREF. The first sub-filter circuit 111b includes the first MOS capacitor MC1 and the first resistor R10. The second sub-filter circuit 115b includes the second MOS capacitor MC2 and the second resistor R30. The first MOS capacitor MC1 may be connected between the first input node IN1 and the second filter node EQP, and the first resistor R10 may be connected between the second filter node EQP and the first filter node VCM_EQ. The second MOS capacitor MC2 may be connected between the second input node IN2 and the third filter node EQN, and the second resistor R30 may be connected between the third filter node EQN and the first filter node VCM_EQ.

The first adjustment circuit 131b includes the first adjustment transistor M11 and the second adjustment transistor M13. The first adjustment transistor M11 may be connected between the first power supply voltage VDD and the first filter node VCM_EQ, and the second adjustment transistor M13 may be connected between the second power supply voltage GND and the first filter node VCM_EQ.

The second adjustment circuit 133b includes a third adjustment transistor M31. The third adjustment transistor M31 may be connected between a fourth filter node FN and the second power supply voltage GND. The third adjustment transistor M31 may operate based on a third control signal CTLC. For example, the third adjustment transistor M31 may have a gate terminal that receives the third control signal CTLC.

In some implementations, the second adjustment circuit 133b may adjust a voltage level of the fourth filter node FN based on the operating mode of the semiconductor memory device. The input capacitance of the receiving circuit 100b may be adjusted by adjusting the voltage level of the fourth filter node FN.

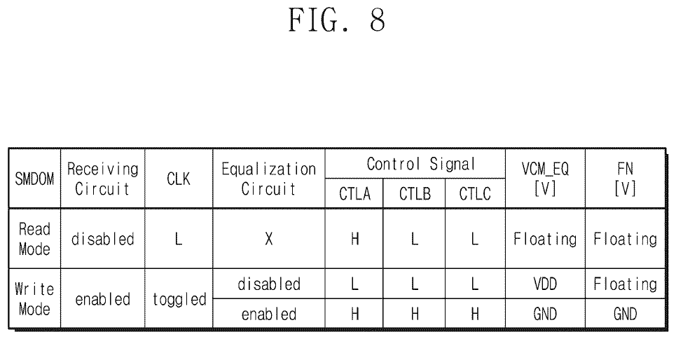

FIG. 8 is a diagram for describing an operation of a receiving circuit of FIG. 7.

Referring to FIGS. 7 and 8, the receiving circuit 100b may operate based on the operating mode SMDOM of the semiconductor memory device.

The receiving circuit 100b may be disabled when the operating mode SMDOM of the semiconductor memory device is a ‘read mode.’ The receiving circuit 100b may be enabled when the operating mode SMDOM of the semiconductor memory device is a ‘write mode.’

In some implementations, in the read mode, the receiving circuit 100b may disable or enable the equalization circuit (e.g., don't care (X)), and the receiving circuit 100b may reduce the input capacitance of the receiving circuit 100b by floating the first filter node VCM_EQ.

In some implementations, in the write mode, the receiving circuit 100b may disable or enable the equalization circuit depending on the communication environment of an interface channel. For example, when the equalization circuit is disabled, the receiving circuit 100b may adjust the first filter node VCM_EQ to the first power supply voltage VDD to reduce the input capacitance of the receiving circuit 100b.

As described above with reference to FIGS. 2 and 3, the input capacitance of the receiving circuit 100b may be measured at the first input node IN1, and the main factor contributing to determining the value of the input capacitance may be the parasitic capacitances of the first input transistor M1 and the capacitance of the first MOS capacitor MC1. However, considering a semiconductor device layout related to a semiconductor device design, the capacitance of the second MOS capacitor MC2 may also additionally contribute to determining the value of the input capacitance of the receiving circuit 100b.

In some implementations, in the read mode, the receiving circuit 100b may float the fourth filter node FN to reduce the input capacitance of the receiving circuit 100b. For example, in response to that the semiconductor memory device operates in the read mode, the third control signal CTLC may correspond to logic low, and the second adjustment circuit 131b may turn off the third adjustment transistor M31 to float the fourth filter node FN. For example, in response to that the semiconductor memory device operates in the read mode, when the receiving circuit 100b is disabled and the fourth filter node FN is floating, both ends of the second MOS capacitor MC2 is floating, so the capacitance of the second MOS capacitor MC2 may be relatively reduced (e.g., the second MOS capacitor MC2 may be in the depletion state). As the capacitance of the second MOS capacitor MC2, which is an additional factor contributing to determining the value of the input capacitance of the receiving circuit 100b, decreases, the input capacitance of the receiving circuit 100b may further decrease.

In some implementations, in the write mode, the receiving circuit 100b may disable or enable the equalization circuit depending on the communication environment of an interface channel.

For example, when the equalization circuit is disabled, the receiving circuit 100b may float the fourth filter node FN to reduce the input capacitance of the receiving circuit 100b. For example, in response to that the semiconductor memory device operates in the write mode and the receiving circuit 100b disables the equalization circuit, the third control signal CTLC may correspond to logic low, and the second adjustment circuit 131b may turn off the third adjustment transistor M31 to float the fourth filter node FN. For example, in response to that the semiconductor memory device operates in the write mode and the receiving circuit 100b disables the equalization circuit, when the receiving circuit 100b is enabled, and the voltage level of the fourth filter node FN is floating, one end (e.g., the fourth filter node FN) of the second MOS capacitor MC2 is floating and the first power supply voltage VDD is applied to the other end (e.g., the third filter node EQN) of the second MOS capacitor MC2, the capacitance of the second MOS capacitor MC2 may be relatively reduced (e.g., the second MOS capacitor MC2 may be in the depletion state), and the input capacitance of the receiving circuit 100b may be further reduced.

For example, when the equalization circuit is enabled, the receiving circuit 100b may operate normally by adjusting the voltage level of the fourth filter node FN to the second power supply voltage GND.

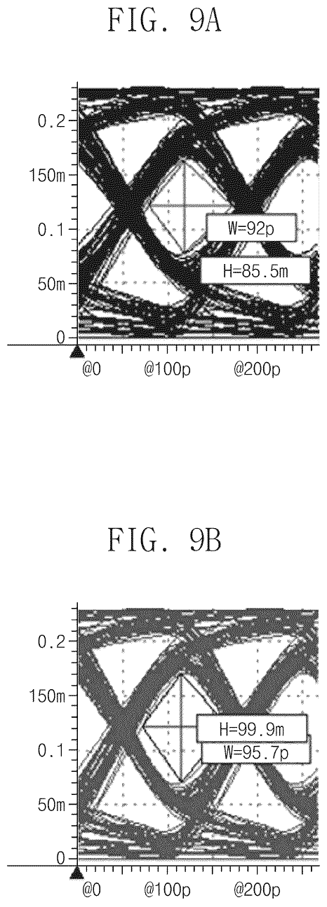

FIGS. 9A and 9B are eye diagrams for describing improvement in performance of receiving circuits of FIG. 2 or FIG. 7.

FIG. 9A may represent an eye diagram of the first input signal INSIG when the first adjustment circuit 131a or 131b or the second adjustment circuit 133b of the receiving circuits 100a and 100b of FIG. 2 or FIG. 7 is not operated, and FIG. 9B may represent an eye diagram of the first input signal INSIG when the first adjustment circuit 131a or 131b or the second adjustment circuit 133b is operated.

Referring to FIGS. 9A and 9B, as a height H of the eye increases from 85.5 mV to 99.9 mV and a width W of the eye increases from 92 ps to 95.7 ps, when the first adjustment circuit 131a or 131b or the second adjustment circuit 133b is operated, the receiving circuits 100a and 100b according to some implementations of the present disclosure may exhibit improved performance in terms of timing jitter and bit error rate (BER) related to the first input signal INSIG.

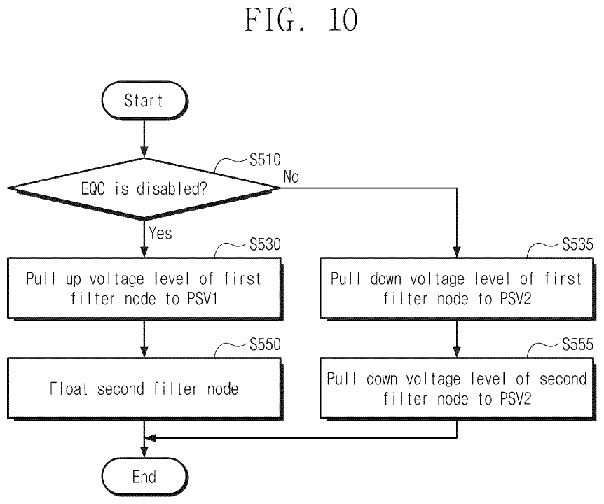

FIG. 10 is a flowchart illustrating some implementations of an operation of a receiving circuit of FIG. 7.

Referring to FIGS. 7 and 10, it may be determined whether the equalization circuit EQC is disabled (S510).

When the equalization circuit EQC is disabled (YES in S510), the voltage level of the first filter node VCM_EQ may be pulled up to the first power supply voltage PSV1 (S530), and the second filter node EQP may be floated (S550).

When the equalization circuit EQC is enabled (NO in S510), the voltage level of the first filter node VCM_EQ may be pulled down to the second power supply voltage PSV2 (S535), and the voltage level of the second filter node EQP may be pulled down to the second power supply voltage PSV2 (S555).

In some implementations, operations S530 and S535 may be performed by the receiving circuit 100b, the input capacitance adjustment circuit, or the first adjustment circuit 131b, operations S550 and S555 may be performed by the receiving circuit 100b, the input capacitance adjustment circuit, or the second adjustment circuit 133b, and the control logic circuit of the semiconductor memory device may provide the control signals for operations S530, S535, S550, and S555 to the receiving circuit 100b.

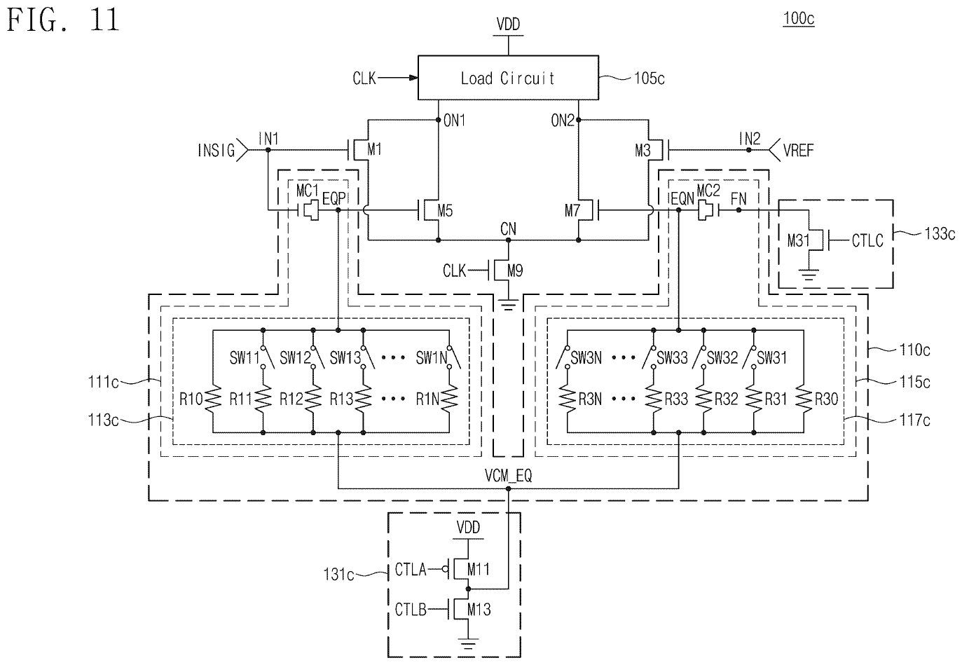

FIG. 11 is a circuit diagram illustrating a receiving circuit, according to some implementations of the present disclosure.

Referring to FIGS. 1, 2, 7, and 11, a receiving circuit 100c may correspond to the receiving circuit 100, the receiving circuit 100a, and the receiving circuit 100b. The receiving circuit 100c includes a load circuit 105c, the first input transistor M1, the second input transistor M3, the first equalization transistor M5, the second equalization transistor M7, the bias transistor M9, a filter circuit 110c, a first adjustment circuit 131c, and a second adjustment circuit 133c. In FIGS. 7 and 11, components having the same reference numerals may perform the same or similar functions, the load circuit 105c may correspond to the load circuit 105b, the filter circuit 110c may correspond to the filter circuit 110b, the first adjustment circuit 131c may correspond to the first adjustment circuit 131b, and the second adjustment circuit 133c may correspond to the second adjustment circuit 133b. For example, the receiving circuit 100c may include the same or similar configuration as the receiving circuit 100b except that it includes a first resistance network 113c and a second resistance network 117c instead of the first resistor R10 and the second resistor R30. Thus, additional descriptions of components that are the same as those of FIG. 7 will be omitted to avoid redundancy.

The filter circuit 110c includes a first sub-filter circuit 111c and a second sub-filter circuit 115c. The first sub-filter circuit 111c may be connected between the first input node IN1 and the first filter node VCM_EQ and may filter the first input signal INSIG. The second sub-filter circuit 115c may be connected between the second input node IN2 and the first filter node VCM_EQ and may filter the second input signal VREF. The first sub-filter circuit 111c includes the first MOS capacitor MC1 and the first resistance network 113c. The second sub-filter circuit 115c includes the second MOS capacitor MC2 and the second resistance network 117c. The first MOS capacitor MC1 may be connected between the first input node IN1 and the second filter node EQP, and the first resistance network 113c may be connected between the second filter node EQP and the first filter node VCM_EQ. The second MOS capacitor MC2 may be connected between the second input node IN2 and the third filter node EQN, and the second resistance network 117c may be connected between the third filter node EQN and the first filter node VCM_EQ. For example, the first sub-filter circuit 111c and the second sub-filter circuit 115c may be high-pass filters that pass only high-frequency components of the first input signal INSIG and the second input signal VREF. The first resistance network 113c and the second resistance network 117c may correspond to the reflection noise compensation circuit 150 of FIG. 1.

In some implementations, the first resistance network 113c includes switches SW11, SW12, SW13, . . . , SWIN and resistors R10, R11, R12, R13, . . . , R1N) (‘N’ is 4 or more integers), and the second resistance network 117c includes switches SW31, SW32, SW33, . . . , SW3N and resistors R31, R32, R33, . . . , R3N. The first resistance network 113c and the first MOS capacitor MC1 may determine the cutoff frequency of the first sub-filter circuit 111c, and the second resistance network 117c and the second MOS capacitor MC2 may determine the cutoff frequency of the second sub-filter circuit 115c. For example, the first resistance network 113c may have a first composite resistance value that varies based on the number of switches SW11 to SWIN that are turned on, and the second resistance network 117c may have a second composite resistance value that varies based on the number of switches SW31 to SW3N that are turned on. The cutoff frequency of the first sub-filter circuit 113c may be determined based on the change in the first composite resistance value, and the cutoff frequency of the second sub-filter circuit 115c may be determined based on the change in the second composite resistance value.

In some implementations, the first resistance network 113c and the second resistance network 117c may adjust the first composite resistance value and the second composite resistance value based on the operating mode of the semiconductor memory device and the value of reflection noise. The cutoff frequencies of the first sub-filter circuit 113c and the second sub-filter circuit 115c may be determined by adjusting the first composite resistance value and the second composite resistance value, and the signal integrity of the input signal INSIG may be improved.

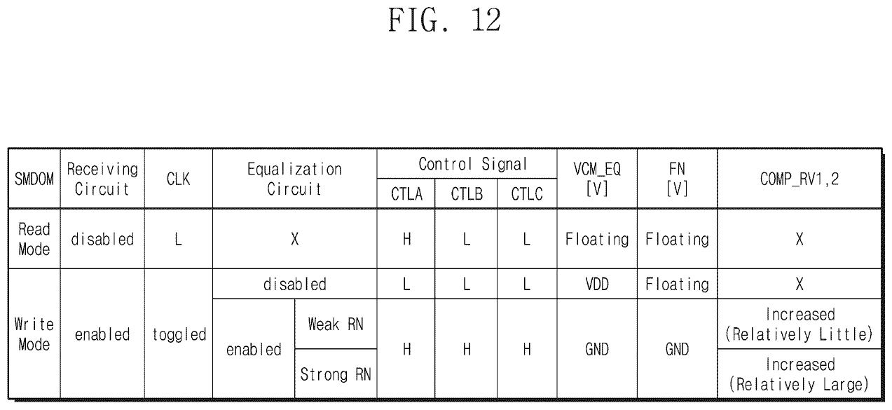

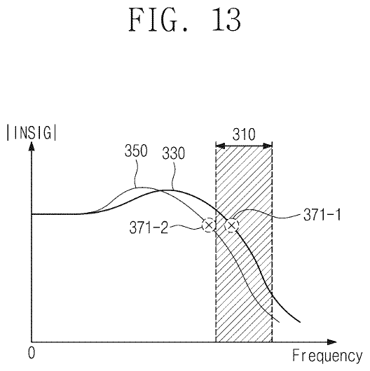

FIG. 12 is a diagram for describing an operation of a receiving circuit of FIG. 11.

Referring to FIGS. 11 and 12, the receiving circuit 100c may operate based on the operating mode SMDOM of the semiconductor memory device.

The receiving circuit 100c may be disabled when the operating mode SMDOM of the semiconductor memory device is a ‘read mode.’ The receiving circuit 100c may be enabled when the operating mode SMDOM of the semiconductor memory device is a ‘write mode.’

In some implementations, in the read mode, the receiving circuit 100c may not adjust (e.g., don't care (X)) a first composite resistance value COMP_RV1 of the first resistance network 113c and a second composite resistance value COMP_RV2 of the second resistance network 117c.

In some implementations, in the write mode, the receiving circuit 100c may disable or enable the equalization circuit depending on the communication environment of an interface channel.

For example, when the equalization circuit is disabled, the receiving circuit 100c may not adjust (e.g., don't care (X)) the first composite resistance value COMP_RV1 and the second composite resistance value COMP_RV2 of the second resistance network 117c.

For example, when the equalization circuit is enabled, the receiving circuit 100c may adjust the first composite resistance value COMP_RV1 and the second composite resistance value COMP_RV2 of the second resistance network 117c depending on the value of the reflection noise.

For example, when the value of the reflection noise is relatively small (e.g., a weak RN), the first resistance network 113c and the second resistance network 117c may increase the first composite resistance value COMP_RV1 and the second composite resistance value COMP_RV2 by a relatively small amount. When the value of the reflection noise is relatively large (e.g., a strong RN), the first resistance network 113c and the second resistance network 117c may increase the first composite resistance value COMP_RV1 and the second composite resistance value COMP_RV2 by a relatively large amount. In proportion to the increases in the first composite resistance value COMP_RV1 and the second composite resistance value COMP_RV2, the decrease amounts in the cutoff frequencies of the first sub-filter circuit 113c and the second sub-filter circuit 115c may increase.

For example, when the value of the reflection noise is less than or equal to a first reference noise value, the first resistance network 113c and the second resistance network 117c may reduce the first composite resistance value COMP_RV1 and the second composite resistance value COMP_RV2 to be less than the first reference resistance value. When the value of the reflection noise is greater than the first reference noise value, the first resistance network 113c and the second resistance network 117c may increase the first composite resistance value COMP_RV1 and the second composite resistance value COMP_RV2 to be greater than the first reference resistance value.

In some implementations, the value of the reflection noise may be determined depending on the communication environment of an interface channel, and information regarding the value of the reflection noise may be provided from a host device external to the semiconductor memory device or may be generated internally by the semiconductor memory device. The control logic circuit of the semiconductor memory device may provide control signals for determining the first composite resistance value COMP_RV1 and the second composite resistance value COMP_RV2 to the receiving circuit 100c.

FIG. 13 is a graph for describing a change in an input signal according to a change in a composite resistance value of a resistance network of FIG. 11.

In FIG. 13, the frequency response of the first input signal INSIG is illustrated. A horizontal axis represents frequency, and a vertical axis represents the absolute value of the first input signal INSIG.

Referring to FIGS. 11, 12, and 13, when the first resistance network 113c and the second resistance network 117c of FIG. 11 do not adjust the first composite resistance value and the second composite resistance value, the frequency response of the input signal INSIG may have a first shape (e.g., 330).

A frequency band 310 may represent the frequency band of reflection noise transferred to the receiving circuit 100c of FIG. 11 through the interface channel of the semiconductor memory device. In this case, the first resistance network 113c and the second resistance network 117c in the receiving circuit 100c may adjust the first composite resistance value and the second composite resistance value to adjust the cutoff frequencies of the first sub-filter circuit 113c and the second sub-filter circuit 113c. For example, the first resistance network 113c may increase the first composite resistance value, the second resistance network 117c may increase the second composite resistance value, so the position of each pole of the first sub-filter circuit 113c and the sub-filter circuit 115c may be moved to the left in a frequency response domain. Accordingly, the frequency response of the first input signal INSIG may change from the first form to a second form (e.g., 350) at the time the first input signal INSIG is transferred to the load circuit 105c. The receiving circuit 100c may adjust the pass band of the first input signal INSIG not to overlap the frequency band of the reflection noise, and may prevent the reflection noise from being amplified by the equalization circuit of the receiving circuit 100c, so the signal integrity of the first input signal INSIG may be improved.

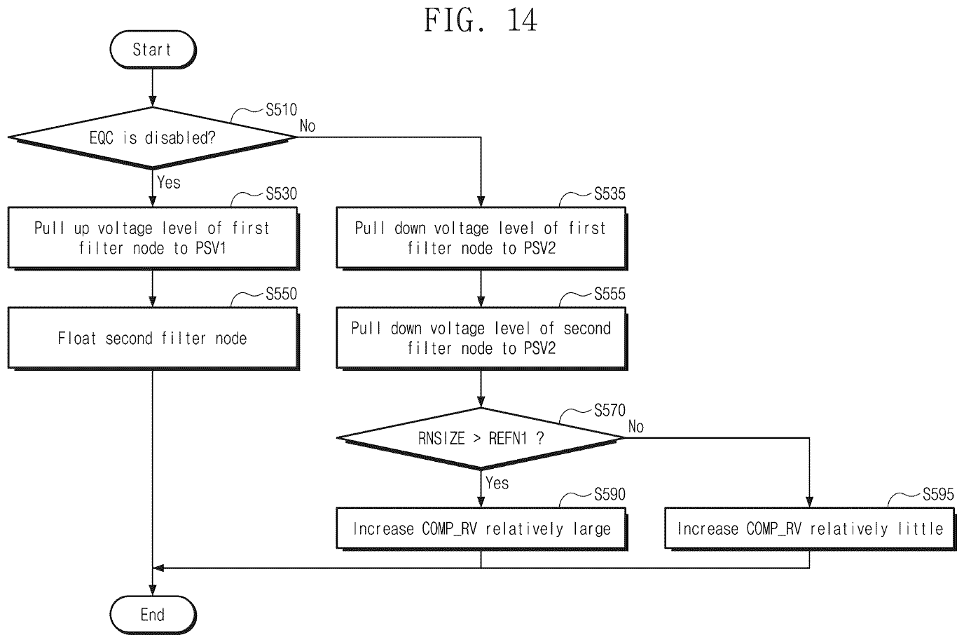

FIG. 14 is a flowchart illustrating some implementations of an operation of a receiving circuit of FIG. 11.

Referring to FIGS. 11 and 14, it may be determined whether the equalization circuit EQC is disabled (S510).

When the equalization circuit EQC is disabled (YES in S510), the voltage level of the first filter node VCM_EQ may be pulled up to the first power supply voltage PSV1 (S530), and the second filter node EQP may be floated (S550).

When the equalization circuit EQC is enabled (NO in S510), the voltage level of the first filter node VCM_EQ may be pulled down to the second power supply voltage PSV2 (S535), and the voltage level of the second filter node EQP may be pulled down to the second power supply voltage PSV2 (S555).

When the equalization circuit EQC is enabled (NO in S510), it may be determined whether a value RNSIZE of the reflection noise is greater than a first reference noise value REFN1 (S570).

When the value of the reflection noise RNSIZE is greater than the first reference noise value REFN1 (YES in S570), the composite resistance value COMP_RV may be increased relatively significantly (S590). When the value of the reflection noise RNSIZE is less than or equal to the first reference noise value REFN1 (NO in S570), the composite resistance value COMP_RV may be increased relatively small (S595). For example, the composite resistance value COMP_RV may be increased significantly in S590 compared to S595. The composite resistance value COMP_RV may increase less in S595 than in S590.

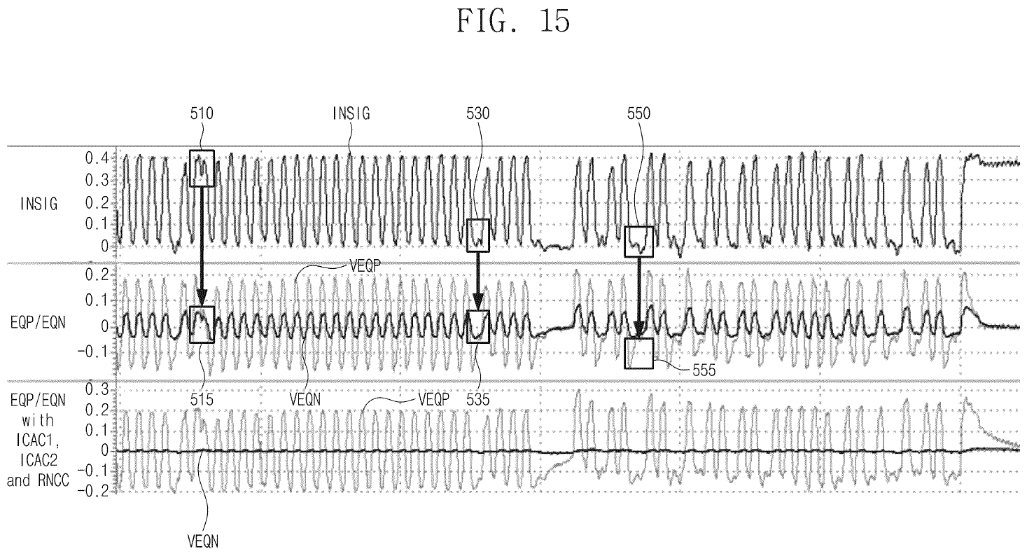

FIG. 15 is a graph for describing improvement in performance of a receiving circuit, according to some implementations of the present disclosure.

In FIG. 15, a signal waveform of the first input signal (e.g., INSIG), signal waveforms (i.e., EQP/EQN) at the second filter node (e.g., EQP) and the third filter node (e.g., EQN), and signal waveforms (i.e., EQP/EQN with ICAC1, ICAC2, and RNCC) at the second filter node and the third filter node are illustrated when the first adjustment circuit (e.g., 131a, 131b, or 131c), the second adjustment circuit (e.g., 133b or 133c), the first resistance network (e.g., 113c), and the second resistance network (e.g., 117c) of the receiving circuits (e.g., 100, 100a, 100b, and 100c) operate.

Referring to FIG. 15, in the signal waveform of the first input signal, portion 510 may represent data ‘11,’ portion 530 may represent data ‘00,’ and portion 550 may represent data ‘000.’

In the signal waveforms of the second filter node and the third filter node, portion 515, portion 535, and portion 555 may illustrate shapes that appear in the receiving circuit of the semiconductor memory device as portions 510, 530, and 550 are distorted while passing through the interface channel.

In the receiving circuits according to implementations of the present disclosure, the first input signal (i.e., EQP/EQN with ICAC1, ICAC2, and RNCC) with the ultimately improved signal integrity may be obtained by operations of the first adjustment circuit, the second adjustment circuit, the first resistance network, and the second resistance network.

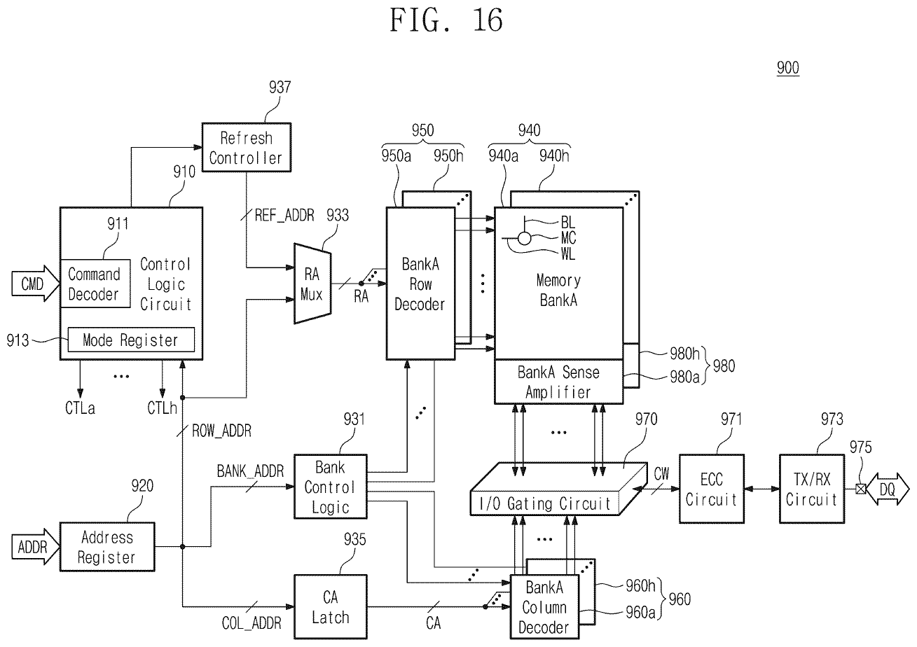

FIG. 16 is a block diagram illustrating a semiconductor memory device including a receiving circuit, according to some implementations of the present disclosure.

Referring to FIG. 16, a memory device 900 includes a control logic circuit 910, an address register 920, bank control logic 931, a row address multiplexer 933, a column address latch 935, a refresh controller 937, a bank array 940, a row decoder 950, a column decoder 960, an input/output (I/O) gating circuit 970, an ECC (error correction code) circuit 971, a data transmission/reception circuit 973, a data input/output pad 975, and bit line sense amplifier sets 980. The control logic circuit 910 includes a command decoder 911 and a mode register 913. For example, the memory device 900 may be a volatile memory device, particularly a dynamic random access memory (DRAM).

The bank array 940 includes a plurality of bank arrays 940a and 940h. The row decoder 950 includes a plurality of bank row decoders 950a and 950h, respectively connected to the plurality of bank arrays 940a and 940h, the column decoder 960 includes a plurality of bank column decoders 960a and 960h, respectively connected to the plurality of bank arrays 940a and 940h, and the bit line sense amplifier sets 980 includes a plurality of bank sense amplifiers 980a and 980h, respectively connected to the plurality of bank arrays 940a and 940h. The plurality of bank arrays 940a and 940h, the plurality of bank row decoders 950a and 950h, and the plurality of bank column decoders 960a and 960h may form a plurality of banks. Each of the bank arrays 940a and 940h includes a plurality of memory cells MCs formed at intersections of a plurality of word lines WLs and a plurality of bit lines BLs.

The address register 920 may receive an address ADDR including a bank address BANK_ADDR, a row address ROW_ADDR, and a column address COL_ADDR from a memory controller. The address register 920 may provide the bank address BANK_ADDR to the bank control logic 931, may provide the row address ROW_ADDR to the row decoder 950 through the row address multiplexer 933, and may provide the column address COL_ADDR to the column decoder 960 through the column address latch 935.

The bank control logic 931 may generate a bank control signal in response to the bank address BANK_ADDR. Based on the bank control signals, the bank row decoders 950a and 950h and the bank column decoders 960a and 960h corresponding to the bank address BANK_ADDR may be activated.

The refresh controller 937 may generate a refresh row address REF_ADDR that sequentially increases or decreases under the control of the control logic circuit 910.

Among the plurality of bank column decoders 960a and 960h, activated bank column decoders may activate the bank sense amplifiers 980a and 980h corresponding to the bank address BANK_ADDR, the row address ROW_ADDR, and the column address COL_ADDR, using the input/output gating circuit 970.

A codeword CW read from one of the plurality of bank arrays 940a and 940h is detected by the bank sense amplifier corresponding to one bank array, and the detected codeword CW may be ECC decoded by the ECC circuit 971 and then may be provided as a DQ signal to the memory controller through the data transmission/reception circuit 973.

Data to be written in one of the plurality of bank arrays 940a and 940h is provided to the ECC circuit 971, the ECC circuit 971 may generate parity bits based on the provided data and may provide a codeword including the provided data and the parity bits to the input/output gating circuit 970, and the input/output gating circuit 970 may write the codeword to one bank array.

The control logic circuit 910 may control the operation of the memory device 900. For example, the control logic circuit 910 may generate control signals to allow the memory device 900 to perform a write operation or a read operation. The command decoder 911 may decode a command CMD received from the memory controller, and the mode register 913 may set the operating mode of the memory device 900. For example, the command decoder 911 may generate the control signals corresponding to the command CMD by decoding a write enable signal, a row address strobe signal, a column address strobe signal, and a chip select signal.

The data transmission/reception circuit 973 may include a transmission circuit and a receiving circuit connected to one data input/output pad 975, and the receiving circuit may include the receiving circuit 100, 100a, 100b, or 100c described above with reference to FIGS. 1, 2, 7, and 11. Accordingly, the data transmission/reception circuit 973 may improve signal integrity of the input signal input through the data input/output pad 975, according to implementations of the present disclosure. In some implementations, the control logic circuit 910 may generate control signals CTLa, . . . . CTLh, and the receiving circuit included in the data transmission/reception circuit 973 may improve the signal integrity of the input signal by controlling the operations of the first adjustment circuit (e.g., 131a, 131b, or 131c), the second adjustment circuit (e.g., 133b or 133c), the first resistance network (e.g., 113c), and the second resistance network (e.g., 117c), based on the control signals CTLa, . . . . CTLh.

As described above, the receiving circuit according to implementations of the present disclosure may adjust the voltage levels of one or more internal nodes included in the filter circuit based on the operating mode of the semiconductor memory device including a write mode and a read mode. The receiving circuit may adjust the voltage levels of the one or more internal nodes in response to that the semiconductor memory device operates in a specific operating mode and the receiving circuit enables/disables the equalization circuit. The receiving circuit adjusts composite resistance values of the resistance networks in response to that the semiconductor memory device operates in a specific operating mode, the receiving circuit enables/disables the equalization circuit, and the magnitude of the reflection noise is above a specific level. The input capacitance of the receiving circuit may be reduced by adjusting the voltage levels of the one or more internal nodes, and the noise component of the input signal may be reduced by adjusting the composite resistance values of the resistance networks. The receiving circuit may improve signal integrity of the input signal by reducing the input capacitance or reducing the noise component.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above description refers to implementations for implementing the present disclosure. Implementations in which a design is changed simply or which are easily changed may be included in the present disclosure as well as the above-described implementations. In addition, technologies that are easily changed and implemented by using the above implementations may be included in the present disclosure. Therefore, the scope of the present disclosure should not be limited to the above-described implementations, but should be determined by equivalents to the claims of the present disclosure as well as the claims described later.

What is claimed is:

1. A receiving circuit comprising:
a first input transistor connected between a first common node and a first output node and configured to receive a first input signal through a first input node;
a second input transistor connected between the first common node and a second output node and configured to receive a second input signal through a second input node;
a first equalization transistor connected in parallel with the first input transistor;
a second equalization transistor connected in parallel with the second input transistor;
a filter circuit including one or more internal nodes and configured to filter the first input signal; and
an input capacitance adjustment circuit configured to adjust one or more voltage levels of the one or more internal nodes based on an operating mode of a semiconductor memory device, the operating mode including a write mode or a read mode.

2. The receiving circuit of claim 1,
wherein the filter circuit includes:
a first sub-filter circuit connected between the first input node and a first filter node; and
a second sub-filter circuit connected between the second input node and the first filter node, and
wherein the input capacitance adjustment circuit is configured to adjust a voltage level of the first filter node based on the operating mode of the semiconductor memory device.

3. The receiving circuit of claim 2,
wherein the semiconductor memory device operates in the read mode, and
wherein the input capacitance adjustment circuit is configured to float the first filter node.

4. The receiving circuit of claim 2,
wherein the semiconductor memory device operates in the write mode, and
wherein the input capacitance adjustment circuit is configured to adjust the voltage level of the first filter node to one of a first power supply voltage and a second power supply voltage.

5. The receiving circuit of claim 4, wherein the input capacitance adjustment circuit is configured to:
pull up the voltage level of the first filter node to the first power supply voltage in response to the receiving circuit disabling an equalization operation; and
pull down the voltage level of the first filter node to the second power supply voltage in response to the receiving circuit enabling the equalization operation.

6. The receiving circuit of claim 5, wherein the input capacitance adjustment circuit includes:
a first adjustment transistor connected between the first power supply voltage and the first filter node and configured to operate based on a first control signal and; and
a second adjustment transistor connected between the second power supply voltage and the first filter node and configured to operate based on a second control signal and.

7. The receiving circuit of claim 2, wherein the first sub-filter circuit includes:
a first metal oxide semiconductor (MOS) capacitor connected between the first input node and a second filter node; and
a first resistor connected between the second filter node and the first filter node.

8. The receiving circuit of claim 7, wherein the first MOS capacitor:
is in a depletion state in response to the semiconductor memory device operating in the read mode,
is in the depletion state in response to the semiconductor memory device operating in the write mode and the receiving circuit disabling an equalization operation, and
is in an inversion state in response to the semiconductor memory device operating in the write mode and the receiving circuit enabling the equalization operation.

9. The receiving circuit of claim 1,
wherein the filter circuit includes:
a first sub-filter circuit connected between the first input node and a first filter node; and
a second sub-filter circuit connected between a second filter node and the first filter node, and
wherein the input capacitance adjustment circuit includes:
a first adjustment circuit configured to adjust a voltage level of the first filter node based on the operating mode of the semiconductor memory device; and
a second adjustment circuit configured to adjust a voltage level of the second filter node based on the operating mode of the semiconductor memory device.

10. The receiving circuit of claim 9,
wherein the semiconductor memory device operates in the read mode, and
wherein the second adjustment circuit is configured to float the second filter node.

11. The receiving circuit of claim 9,
wherein the semiconductor memory device operates in the write mode, and
wherein the second adjustment circuit is configured to float the second filter node in response to the receiving circuit disabling the equalization operation.

12. The receiving circuit of claim 9, wherein the first sub-filter circuit includes:
a first metal oxide semiconductor (MOS) capacitor connected between the first input node and a third filter node; and
a first resistance network connected between the third filter node and the first filter node and having a variable first composite resistance value.

13. The receiving circuit of claim 12,
wherein the semiconductor memory device operates in the write mode,
wherein a value of a reflection noise is greater than a first reference noise value, and
wherein the first resistance network increases the first composite resistance value to be greater than a first reference resistance value.

14. The receiving circuit of claim 13, wherein the value of the reflection noise is less than or equal to the first reference noise value, and
wherein the first resistance network decreases the first composite resistance value to be less than the first reference resistance value.

15. A receiving circuit comprising:
a first input transistor connected between a first common node and a first output node and configured to receive a first input signal through a first input node;
a second input transistor connected between the first common node and a second output node and configured to receive a second input signal through a second input node;
an equalization circuit including one or more internal nodes and configured to equalize the first input signal; and
an input capacitance adjustment circuit configured to adjust one or more voltage levels of the one or more internal nodes based on an operating mode of a semiconductor memory device, the operating mode including a write mode or a read mode.

16. The receiving circuit of claim 15,
wherein the equalization circuit includes: a first sub-filter circuit connected between the first input node and a first filter node, and
wherein the input capacitance adjustment circuit is configured to adjust a voltage level of the first filter node based on the operating mode of the semiconductor memory device.

17. The receiving circuit of claim 15,
wherein the equalization circuit includes:
a first sub-filter circuit connected between the first input node and a first filter node; and
a second sub-filter circuit connected between a second filter node and the first filter node, and
wherein the input capacitance adjustment circuit is configured to adjust a voltage level of the first filter node and a voltage level of the second filter node based on the operating mode of the semiconductor memory device.

18. The receiving circuit of claim 17, wherein the first-sub filter circuit includes:
a first metal oxide semiconductor (MOS) capacitor connected between the first input node and a third filter node; and
a first resistance network connected between the third filter node and the first filter node and having a variable first composite resistance value.

19. The receiving circuit of claim 18, wherein the input capacitance adjustment circuit is configured to:
float the voltage levels of the first filter node and the second filter node in response to the semiconductor memory device operating in the read mode; and
adjust the voltage level of the first filter node to a first power supply voltage and float the second filter node in response to the semiconductor memory device operating in the write mode and the equalization circuit being disabled.

20. A receiving circuit comprising:
a first input transistor connected between a first common node and a first output node and configured to receive a first input signal through a first input node;
a second input transistor connected between the first common node and a second output node and configured to receive a second input signal through a second input node;
a first equalization transistor connected in parallel with the first input transistor;
a second equalization transistor connected in parallel with the second input transistor;
a filter circuit configured to filter the first input signal, the filter circuit including a first filter node, a second filter node, and a third filter node; and
an input capacitance adjustment circuit configured to adjust a voltage level of the first filter node and a voltage level of the second filter node based on an operating mode of a semiconductor memory device, the operating mode including a write mode or a read mode,
wherein the filter circuit includes:
a first sub-filter circuit connected between the first input node and the first filter node; and
a second sub-filter circuit connected between the second filter node and the first filter node, and
wherein the first sub-filter circuit includes:
a first metal oxide semiconductor (MOS) capacitor connected between the first input node and a third filter node; and
a first resistance network connected between the third filter node and the first filter node and having a variable first composite resistance value.
